(19) United States
(12) Patent Application Publication
(10) Pub. No.: US 2014/0334926 A1
(43) Pub. Date: Nov. 13, 2014

(54) MOUNTING DEVICE FOR FAN

(71) Applicant: HON HAI PRECISION INDUSTRY CO., LTD., New Taipei (TW)

(72) Inventor: ZHENG-HENG SUN, New Taipei (TW)

(73) Assignee: HON HAI PRECISION INDUSTRY CO., LTD., New Taipei (TW)

(21) Appl. No.: 14/141,436

(22) Filed: Dec. 27, 2013

(30) Foreign Application Priority Data
May 10, 2013 (CN) 2013101695179

(51) Int. Cl. H05K 7/20

(52) U.S. Cl. CPC H05K 7/20554
USPC 415/213.1

(57) ABSTRACT

A mounting device for fixing fans comprises a bottom plate and a top plate. The fans are set between the bottom plate and the top plate. The bottom plate forms a number of rods. The fan comprises two opposite boards. A number of fixing assemblies are arranged on the boards. Each fixing assembly defines a number of fixing holes for receiving corresponding rods. A number of springs are arranged between the bottom plate and the fixing assemblies.

### CROSS-REFERENCE TO RELATED APPLICATION

Relevant subject matter is disclosed in a pending U.S. patent application, titled “MOUNTING DEVICE FOR FAN”, filed on May 18, 2012, with the application Ser. No. 13/474,729, which is assigned to the same assignee as this patent application.

### BACKGROUND

1. Technical Field

The present disclosure relates to a device for mounting fans.

2. Description of Related Art

Many electronic devices use fans to cool internal components. However, the fans are often mounted to a rack by a plurality of screws, and then further mounted in an electronic device together with the rack, which adds additional costs of mounting the racks. Therefore, there is room for improvement in the art.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is a partial exploded, isometric view of an exemplary embodiment of a mounting device, together with a plurality of fans.

FIG. 2 is an enlarged view of a fan of FIG. 1.

FIG. 3 is an assembled, plan view of the mounting device and the fans of FIG. 1.

### DETAILED DESCRIPTION

The disclosure, comprising the accompanying drawings, is illustrated by way of example and not by way of limitation. It should be noted that references to “an” or “one” embodiment in this disclosure are not necessarily to the same embodiment, and such references mean “at least one”.

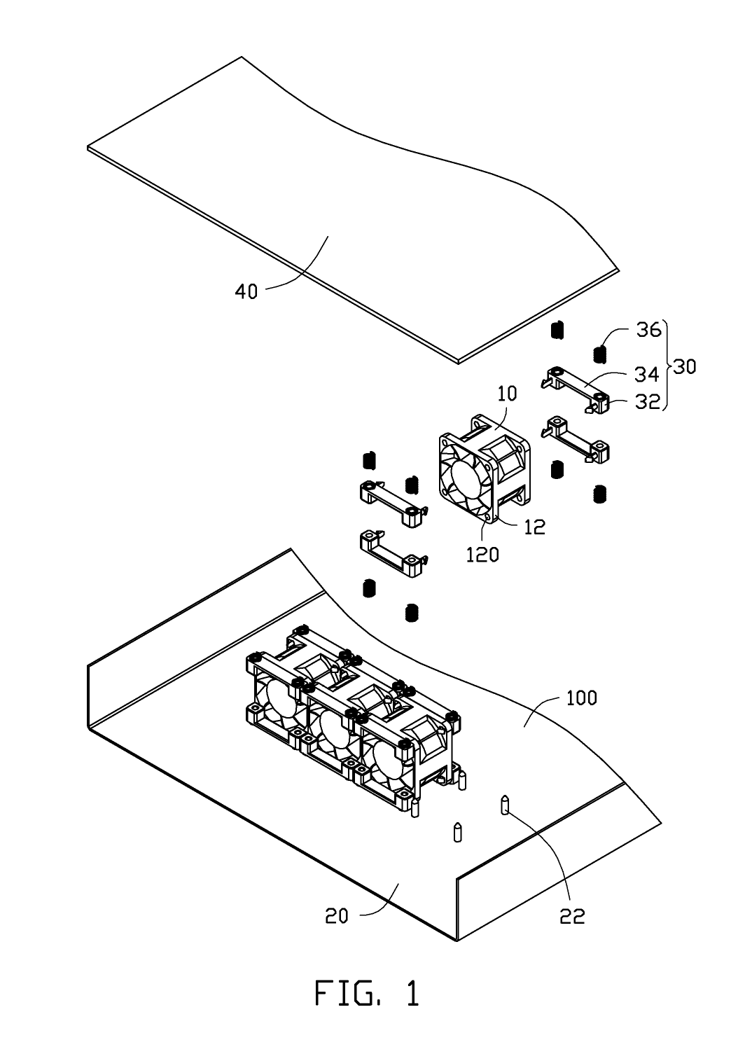

FIG. 1 shows an exemplary embodiment of a mounting device for fixing a plurality of fans 10. The mounting device comprises a chassis 100, and a plurality of fixing assemblies 30.

In one embodiment, each fan 10 comprises two boards 12 spaced from each other. Each board 12 defines four corner holes 120 in four corners of the board 12, respectively.

The chassis 100 comprises a bottom board 20 and a top board 40.

The bottom board 20 forms a plurality of rods 22. Each rod 22 forms a tapered top end.

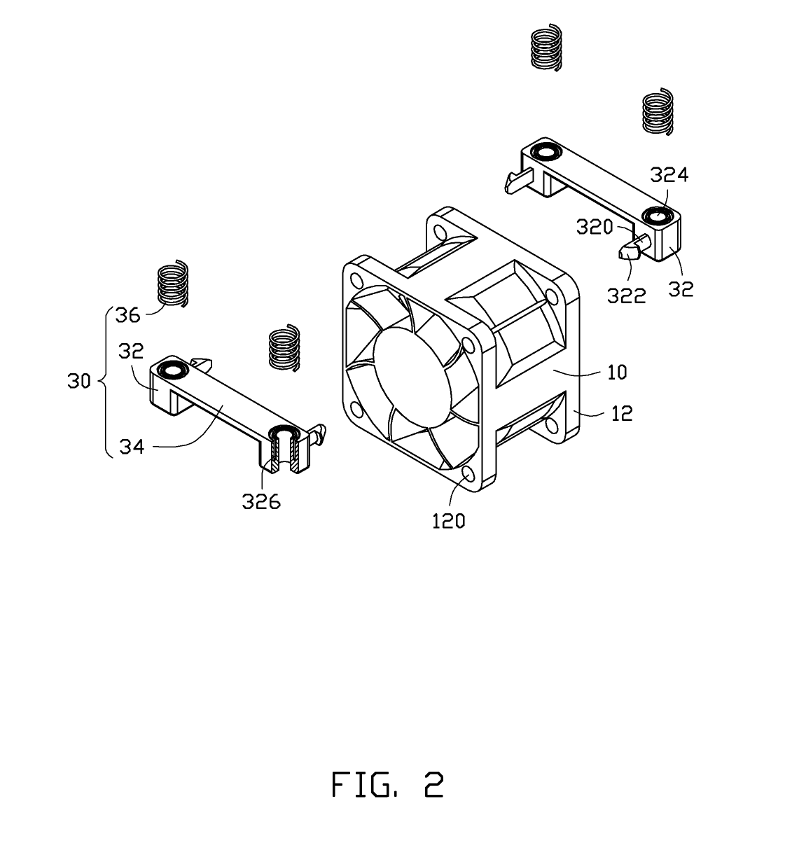

Referring to FIG. 2, each fixing assembly 30 comprises two supporting portions 32, a base plate 34 connected between the supporting portions 32, and two elastic members 36. In one embodiment, the elastic members 36 are springs. A fixing arm 320 extends substantially perpendicularly away from each supporting portion 32 and towards a same direction. The fixing arms 320 extend substantially parallelly to the base plate 34. Each fixing arm 320 forms a hook 322 at a distal end there. Each of the supporting portions 32 defines a fixing hole 324 and an annular slot 326 surrounding the fixing hole 324.

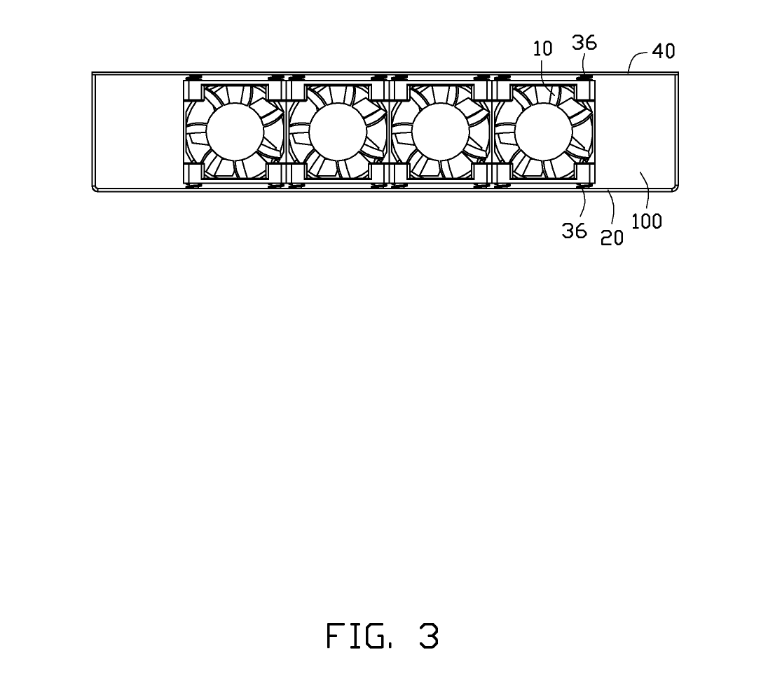

Referring to FIG. 3, in mounting each fan 10, a first end portion of the elastic members 36 is installed in a corresponding slot 326 of the fixing assembly 30. Four fixing assemblies 30 together with the elastic members 36 are attached to the boards 12 of each fan 10, such that a top and bottom portion of each board 12 is attached to one fixing assembly 30. Each fixing arm 320 of the fixing assemblies 30 is received through a corresponding corner hole 120, such that the hooks 322 engage with an inner surface of the boards 12. The elastic members 36 of the fixing assemblies 30 installed to the top portions of the boards 12 (hereinafter “the upper elastic members”) protrude up, and the elastic members 36 of the fixing assemblies 30 installed to the bottom portions of the boards 12 (hereinafter the “lower elastic members”) protrude down. The lower elastic members 36 are sleeved around four corresponding rods 22 of the bottom board 20, and the rods 22 are received through the corresponding fixing holes 324. The lower elastic members 36 are supported on the bottom board 20. The top board 40 is covered over the bottom board 20, such that a bottom surface of the top board 40 resists against ends of the upper elastic members 36. Thus, the fans 10 are fixed between the top board 40 and the bottom board 20. The upper elastic members 36 maintain a space between the top board 40 and a top side of the fans 10, and the lower elastic members 36 maintain a space between the bottom board 20 and a bottom side of the fans 10. Thus, the elastic members 36 absorb vibration generated by the fans 10. In another embodiment, the elastic members 36 can be replaced by other suitable elastic elements such as rubber blocks.

It is believed that the present embodiments and their advantages will be understood from the foregoing description, and various changes may be made thereto without departing from the spirit and scope of the description or sacrificing all of their material advantages, the examples hereinbefore described merely being exemplary embodiments.

What is claimed is:

1. A mounting device for mounting a fan having two opposite boards, comprising:
a chassis comprising a bottom board;
a plurality of rods extended up from the bottom board;
a plurality of first fixing assemblies comprising a plurality of first elastic members, each first fixing assembly defining a plurality of fixing holes;
wherein, in fixing the fan, the plurality of first fixing assemblies are attached to the boards of the fan, the plurality of rods extend in the fixing holes to fix the fan on the bottom board, and the plurality of first elastic members is positioned between the plurality of first fixing assemblies and the bottom board to maintain a space between the bottom board and the fan.

2. The mounting device of claim 1, further comprising a plurality of second fixing assemblies comprising a plurality of second elastic members, wherein the chassis further comprises a top board, and in fixing the fan, the plurality of second elastic members is positioned between the plurality of second fixing assemblies and the top board to maintain a space between the top board and the fan.

3. The mounting device of claim 2, wherein each of the plurality of first and second fixing assemblies comprises two supporting portions and a base plate connected between the supporting portions, the fixing holes are defined in the supporting portions.

4. The mounting device of claim 3, wherein each of first and second fixing assemblies further comprises two fixing arms substantially perpendicularly away from each supporting portion and toward a same direction, and each fixing arm forms a hook at a distal end thereof, the hooks are to be engaged with the boards of the fan.

5. The mounting device of claim 3, wherein each supporting portion defines an annular slot surrounding a corresponding one of the fixing holes, and an first end of a corresponding one of the first or second elastic members is received in the slot, a second end of the corresponding elastic member resists against either the bottom board, or the top board.
